(19) United States
(12) Patent Application Publication
(10) Pub. No.: US 2025/0212410 A1
(43) Pub. Date: Jun. 26, 2025

(54) SEMICONDUCTOR MEMORY DEVICE AND METHOD FOR MANUFACTURING THE SAME

(71) Applicant: Kioxia Corporation, Tokyo (JP)

(72) Inventors: Junichi KANEYAMA, Yokkaichi Mie (JP); Tatsunori ISOGAI, Yokkaichi Mie (JP)

(73) Assignee: Kioxia Corporation, Tokyo (JP)

(21) Appl. No.: 18/826,362

(22) Filed: Sep. 6, 2024

(30) Foreign Application Priority Data
Dec. 20, 2023 (JP) 2023-215013

(51) Int. Cl. H10B 43/30; H10B 43/27

(52) U.S. Cl. CPC H10B 43/30; H10B 43/27

(57) ABSTRACT

A semiconductor memory device according to the present embodiment includes a stacked body, a semiconductor layer, a first insulating film, a charge storage film, a second insulating film, a third insulating film, and an insulating portion. The stacked body is a stacked body in which an electrode layer and an insulating layer are alternately stacked in a first direction. The second insulating film is disposed between the stacked body and the charge storage film along the first direction. The third insulating film is disposed between the insulating layer and the second insulating film. The insulating portion is disposed in an end portion on a side of the third insulating film of the insulating layer, the insulating portion overlapping the electrode layer as viewed in the first direction. A density of the insulating portion differs from a density of the insulating layer.

### CROSS REFERENCE TO RELATED APPLICATIONS

This application is based upon and claims the benefit of priority from the prior Japanese Patent Application No. 2023-215013, filed on Dec. 20, 2023, the entire contents of which are incorporated herein by reference.

### FIELD

The embodiments of the present invention relate to a semiconductor memory device and a method for manufacturing the same.

### BACKGROUND

As a semiconductor memory device, a NAND flash memory in which memory cells are three-dimensionally arranged has been known. In the NAND flash memory, a stacked body in which a plurality of electrode layers and insulating layers are alternately stacked is provided with a memory hole extending through the stacked body. By providing a charge storage layer and a semiconductor layer in the memory hole, a memory string in which a plurality of memory cells is connected in series is formed. Data is stored in the memory cells by controlling the charge amount retained in the charge storage layer.

### BRIEF DESCRIPTION OF THE DRAWINGS

FIG. 1A is a schematic cross-sectional view of a memory cell of a semiconductor memory device of a first embodiment;

FIG. 1B is a schematic cross-sectional view of the memory cell of the semiconductor memory device of the first embodiment;

FIG. 2 is a cross-sectional view showing a semiconductor memory device manufacturing process according to the first embodiment;

FIG. 3 is a cross-sectional view showing the semiconductor memory device manufacturing process of the first embodiment;

FIG. 4 is a cross-sectional view showing the semiconductor memory device manufacturing process of the first embodiment;

FIG. 5 is a cross-sectional view showing the semiconductor memory device manufacturing process of the first embodiment;

FIG. 6 is a cross-sectional view showing the semiconductor memory device manufacturing process of the first embodiment;

FIG. 7 is a cross-sectional view showing the semiconductor memory device manufacturing process of the first embodiment;

FIG. 8 is a cross-sectional view showing the semiconductor memory device manufacturing process of the first embodiment;

FIG. 9 is a cross-sectional view showing the semiconductor memory device manufacturing process of the first embodiment;

FIG. 10 is a cross-sectional view showing the semiconductor memory device manufacturing process of the first embodiment;

FIG. 11 is a cross-sectional view showing a semiconductor memory device manufacturing process according to a comparative example;

FIG. 12 is a cross-sectional view showing the semiconductor memory device manufacturing process of the comparative example;

FIG. 13 is a cross-sectional view showing the semiconductor memory device manufacturing process of the comparative example;

FIG. 14 is a cross-sectional view showing a semiconductor memory device manufacturing process according to a second embodiment;

FIG. 15 is a cross-sectional view showing the semiconductor memory device manufacturing process of the second embodiment;

FIG. 16 is a cross-sectional view showing the semiconductor memory device manufacturing process of the second embodiment;

FIG. 17 is a cross-sectional view showing a semiconductor memory device manufacturing process according to a third embodiment;

FIG. 18 is a cross-sectional view showing the semiconductor memory device manufacturing process of the third embodiment;

FIG. 19 is a cross-sectional view showing the semiconductor memory device manufacturing process of the third embodiment; and

FIG. 20 is a cross-sectional view showing the semiconductor memory device manufacturing process of the third embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor memory device according to the present embodiment includes a stacked body, a semiconductor layer, a first insulating film, a charge storage film, a second insulating film, a third insulating film, and an insulating portion. The stacked body is a stacked body in which an electrode layer and an insulating layer are alternately stacked in a first direction. The semiconductor layer is disposed in the stacked body along the first direction. The first insulating film is disposed between the stacked body and the semiconductor layer along the first direction. The charge storage film is disposed between the stacked body and the first insulating film along the first direction. The second insulating film is disposed between the stacked body and the charge storage film along the first direction. The third insulating film is disposed between the insulating layer and the second insulating film. The insulating portion is disposed in an end portion on a side of the third insulating film of the insulating layer, the insulating portion overlapping the electrode layer as viewed in the first direction. A density of the insulating portion differs from a density of the insulating layer.

### First Embodiment

A semiconductor memory device of a first embodiment is a three-dimensional NAND flash memory.

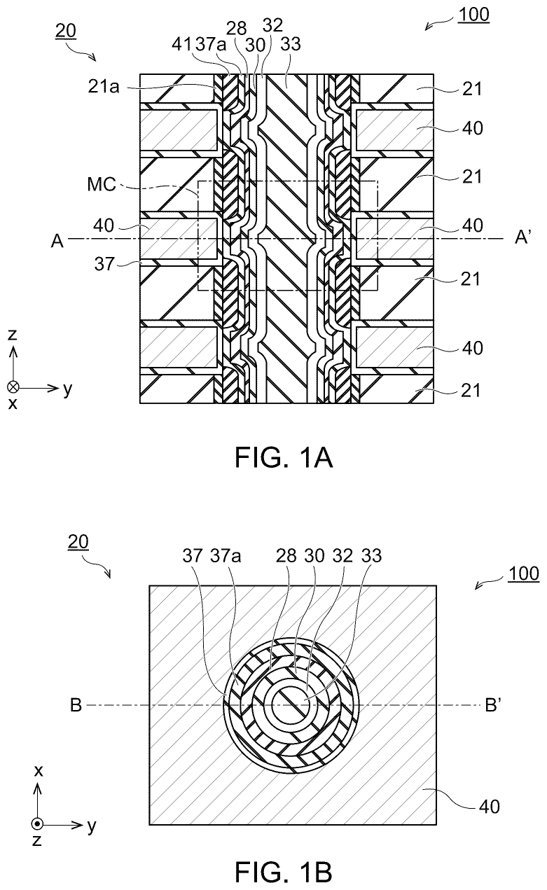

FIG. 1A and FIG. 1B are schematic cross-sectional views of a memory cell array 100 of the semiconductor memory device of the first embodiment. FIG. 1A and FIG. 1B show cross sections of a plurality of memory cells MC of one memory string in the memory cell array 100.

FIG. 1A is a y-z cross-sectional view of the memory cell array 100. FIG. 1A is a cross section taken along BB′ of FIG. 1B. FIG. 1B is an x-y cross-sectional view of the memory cell array 100. FIG. 1B is a cross section taken along AA′ of FIG. 1A. In FIG. 1A, a region enclosed by a broken line is one memory cell MC.

As shown in FIG. 1A and FIG. 1B, the memory cell array 100 includes a plurality of word lines 40, a semiconductor layer 32, a plurality of insulating layers 21, a plurality of insulating portions 21a, a tunnel insulating film 30, a charge storage film 28, a plurality of block films 37a, a plurality of block films 37, a plurality of insulating films 41, and a core insulating film 33. The plurality of word lines 40 and the plurality of insulating layers 21 form a stacked body 20. An “electrode layer” includes the word line 40 and the block film 37.

The memory cell array 100 is provided, for example, on a semiconductor substrate (not shown). The semiconductor substrate includes a surface parallel to an x-direction and a y-direction.

The word lines 40 and the insulating layers 21 are alternately stacked in a z-direction (first direction) on the semiconductor substrate. The word lines 40 are arranged at a distance from each other in the z-direction. The word lines 40 are repeatedly arranged at a distance from each other in the z-direction. The plurality of word lines 40 and the plurality of insulating layers 21 form the stacked body 20. The word lines 40 function as a control electrode of a memory cell transistor.

The word line 40 is a plate-like conductor. The word line 40 is, for example, metal, metal nitride, metal carbide, or a semiconductor. The word line 40 is, for example, tungsten (W). The thickness in the z-direction of the word line 40 is, for example, equal to or greater than 5 nm and equal to or smaller than 20 nm.

The insulating layer 21 separates the word line 40 and the word line 40. The insulating layer 21 electrically separates the word line 40 and the word line 40.

The insulating layer 21 is, for example, oxide, oxynitride, or nitride. The insulating layer 21 includes, for example, oxide silicon. The thickness in the z-direction of the insulating layer 21 is, for example, equal to or greater than 5 nm and equal to or smaller than 20 nm.

An insulating portion 21a is provided in an end portion on an insulating film 41 side of the insulating layer 21. The insulating portion 21a is provided between the insulating layer 21 and the insulating film 41. The insulating portion 21a overlaps the electrode layer including the word line 40 and the block film 37 as viewed in the z-direction. The insulating portion 21a overlaps a portion (for example, a first portion) extending in the z-direction of the block film 37 as viewed in the z-direction. The insulating portion 21a includes, for example, oxide silicon.

The semiconductor layer 32 is provided in the stacked body 20. The semiconductor layer 32 extends in the z-direction. The semiconductor layer 32 extends in a direction perpendicular to a surface of the semiconductor substrate.

The semiconductor layer 32 is provided in such a manner as extending through the stacked body 20. The semiconductor layer 32 is surrounded by the plurality of word lines 40. The semiconductor layer 32 is, for example, cylindrical. The semiconductor layer 32 functions as a channel of the memory cell transistor.

The semiconductor layer 32 is, for example, a polysilicon semiconductor. The semiconductor layer 32 is, for example, polysilicon.

The tunnel insulating film 30 is provided between the semiconductor layer 32 and the word lines 40. The tunnel insulating film 30 is provided between the semiconductor layer 32 and the charge storage film 28.

The tunnel insulating film 30 has a function to allow charge to pass therethrough in accordance with voltage applied between the word lines 40 and the semiconductor layer 32.

The tunnel insulating film 30 includes, for example, silicon (Si) and oxygen (O). The tunnel insulating film 30 includes, for example, silicon (Si), oxygen (O), and nitrogen (N).

The tunnel insulating film 30 includes, for example, oxide silicon or silicon oxynitride. The tunnel insulating film 30 is, for example, an oxide silicon film, a silicon oxynitride film, and a stacked film of oxide silicon films.

The thickness in the y-direction of the tunnel insulating film 30 is, for example, equal to or greater than 3 nm and equal to or smaller than 8 nm.

The charge storage film 28 is provided between the tunnel insulating film 30 and the block film 37a. The charge storage film 28 extends in the z-direction.

The charge storage film 28 includes silicon (Si) and nitrogen (N). The charge storage film 28 includes, for example, silicon nitride. The charge storage film 28 is, for example, a silicon nitride film.

The charge storage film 28 includes, for example, silicon (Si), nitrogen (N), and oxygen (O). The charge storage film 28 includes, for example, silicon oxynitride.

The thickness in the y-direction of the charge storage film 28 is, for example, equal to or greater than 1 nm and equal to or smaller than 5 nm. The charge storage film 28 includes, in the y-direction of FIG. 1A, a portion opposing the insulating layer 21 and a portion opposing the electrode layer. The thickness of the portion opposing the electrode layer is greater than the thickness of the portion opposing the insulating layer 21.

The charge storage film 28 has a function of trapping and storing charge. The charge is, for example, an electron. In accordance with the amount of charge stored in the charge storage film 28, a threshold voltage of the memory cell transistor changes. With the use of the change in the threshold voltage, one memory cell MC can store data.

For example, due to the change in the threshold voltage of the memory cell transistor, the voltage at which the memory cell transistor is turned on changes. For example, when a state of a higher threshold voltage is defined as data “0” and a state of a lower threshold voltage is defined as data “1”, the memory cell MC can store one bit data of “0” and “1”.

The block films 37a are provided in such a manner as continuously extending in the z-direction along the charge storage film 28. The block film 37a directly contacts, in the y-direction, the portion extending in the z-direction of the block film 37.

The block film 37a has a function of blocking current flowing between the charge storage film 28 and the word line 40.

The block film 37a includes, for example, oxide silicon. The block film 37a is, for example, a silicon oxide film.

The block film 37 is provided between the block film 37a and the word line 40. The block film 37 contacts the insulating layer 21 in the z-direction. The block film 37 includes the portion (for example, the first portion) arranged along the z-direction and a portion (for example, a second portion) arranged along a direction (for example, the y-direction of FIG. 1A) crossing the z-direction.

The block film 37 has a function of blocking current flowing between the charge storage film 28 and the word line 40.

The block film 37 includes, for example, a metal oxide such as an aluminum oxide. The block film 37 is, for example, an aluminum oxide layer.

The insulating film 41 is provided between the insulating layer 21 and the block film 37a. The insulating film 41 includes, for example, oxide silicon. The insulating film 41 is, for example, a silicon oxide film.

The core insulating film 33 is provided in the stacked body 20. The core insulating film 33 extends in the z-direction. The core insulating film 33 is provided in such a manner as extending through the stacked body 20. The core insulating film 33 is surrounded by the semiconductor layer 32. The core insulating film 33 is surrounded by the plurality of word lines 40. The core insulating film 33 is in a columnar shape. The core insulating film 33 is, for example, in a cylindrical shape.

The core insulating film 33 is, for example, oxide, oxynitride, or nitride. The core insulating film 33 includes, for example, oxide silicon. The core insulating film 33 is, for example, an oxide silicon layer.

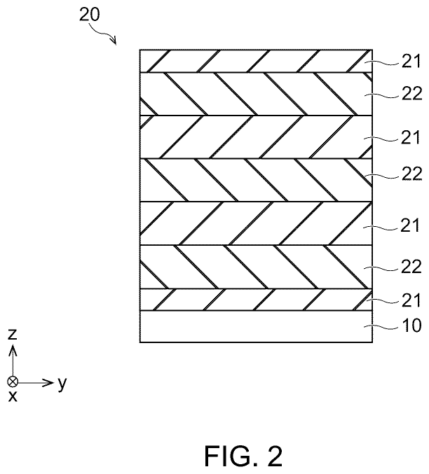

A semiconductor memory device manufacturing method according to the first embodiment will be described with reference to FIG. 2 to FIG. 10. The semiconductor memory device of this embodiment is manufactured by, for example, a method shown below. First, as shown in FIG. 2, the insulating layers 21 and sacrificial layers 22 are alternately stacked on a semiconductor substrate 10. In this manner, the stacked body 20 stacked in the z-direction (the up-down direction in the drawing) is formed. The insulating layer 21 is, for example, a silicon oxide layer. The sacrificial layer 22 is, for example, a silicon nitride layer.

The insulating layers 21 and the sacrificial layers 22 are formed by, for example, a CVD (chemical vapor deposition) method. A part of the insulating layers 21 serves as an interlayer dielectric.

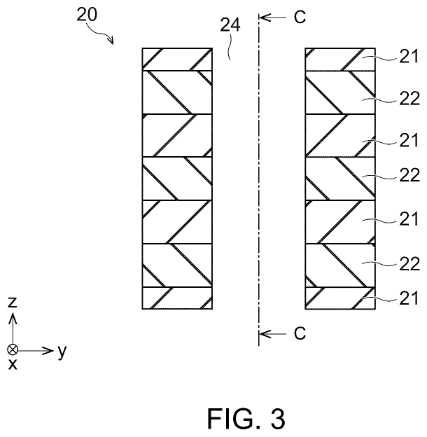

Next, as shown in FIG. 3, a memory hole 24 along the z-direction is formed in the stacked body 20. In FIG. 3 and the following drawings, the semiconductor substrate 10 is omitted. The memory hole 24 extends through the stacked body 20 formed by the insulating layers 21 and the sacrificial layers 22. The memory hole 24 is formed, for example, using a lithography method and a RIE (reactive ion etching) method. In the following description, since the cross section is symmetric with respect to a center line C-C shown in FIG. 3, the cross section on the left side of the center line C-C will be described.

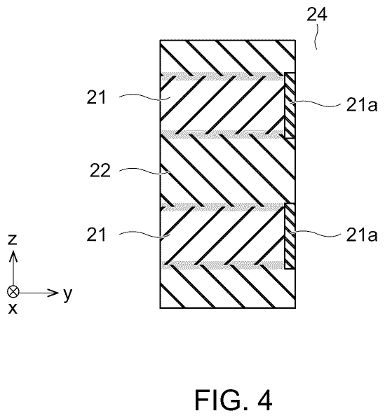

Next, as shown in FIG. 4, the insulating portion 21a that overlaps the sacrificial layer 22 as viewed in the z-direction is formed in the end portion, which is exposed from an inner side surface of the memory hole 24, of the insulating layer 21. More specifically, the oxygen concentration of a portion including an end face, which is exposed from the inner side surface of the memory hole 24, of the insulating layer 21 is made higher than the oxygen concentration of a portion including a boundary between the sacrificial layer 22 and the insulating layer 21. In this manner, the insulating portion 21a having the oxygen concentration higher than that of the boundary is formed. In other words, the insulating portion 21a is arranged in an inner portion of the stacked body 20 relative to an end face of the stacked body 20. The Z-Y cross-sectional shape of the insulating portion 21a is, for example, substantially rectangular.

Note that as shown in FIG. 4 and the following drawings, it is likely that a transition layer as denoted by gray hatching in FIG. 4 is formed in the boundary between the insulating layer 21 and the sacrificial layer 22 in the Z-direction. The transition layer is, for example, a mixed layer of SiN and SiO₂, a layer with SIN entered in the insulating layer 21 of SiO₂, or a layer with SiO₂ entered in the sacrificial layer 22 of SiN. The transition layer includes, for example, SiON in some cases. Therefore, a center portion of the insulating layer 21 includes a substantially single composition of SiO₂, while the transition layer includes a composition other than SiO₂.

Thus, as shown in FIG. 4, the oxygen concentration of the portion including the exposed end face of the insulating layer 21 is made higher than that of the boundary between the sacrificial layer 22 and the insulating layer 21. In this manner, the insulating portion 21a including a substantially single composition of SiO₂ is formed. As a result, the transition layer exposed on the inner side surface of the memory hole 24 can be eliminated.

The insulating portion 21a is formed by performing oxidation treatment on the inner side surface of the memory hole 24. Through the oxidation treatment, the insulating layer 21 exposed from the inner side surface of the memory hole 24 and the transition layer are oxidized. The oxidation treatment is, for example, dry oxidation or radical oxidation. In the radical oxidation, for example, the oxidation is performed using radical derived from H₂O, O₂, or/and an H₂ gas. Note that the surface of the sacrificial layer 22 could also be oxidized. In this case, exposing is performed by etch back. Depending on the dry oxidation or the radical oxidation, the oxidation amount of the sacrificial layer 22 varies in some cases. For example, the oxidation amount of the sacrificial layer 22 by performing the radical oxidation is greater than the oxidation amount of the sacrificial layer 22 by performing the dry oxidation.

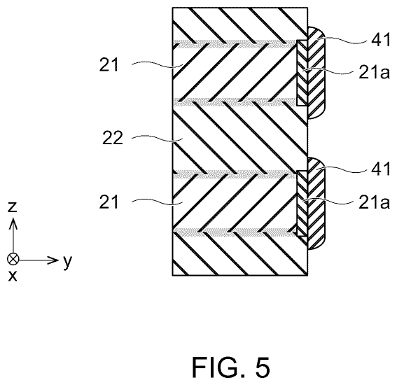

Next, as shown in FIG. 5, the insulating film 41 is selectively formed on the insulating portion 21a on the inner side surface of the memory hole 24. More specifically, by performing selective deposition (area selective deposition: ASD), the insulating film 41 is selectively grown from the insulating portion 21a (with the surface of the insulating portion 21a as a starting point). In this manner, an opening of the insulating film 41 is formed in a region corresponding to the sacrificial layer 22.

The insulating portion 21a is formed as a base for the insulating film 41 so that the insulating film 41 can be formed in a more appropriate shape as will be described later. As a result, the film shape of the insulating film 41 can be improved.

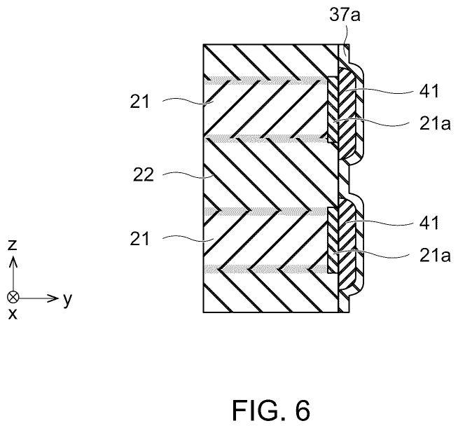

Next, as shown in FIG. 6, the block film 37a is formed on the sacrificial layer 22 and the insulating film 41. The block film 37a is formed so as to directly contact the sacrificial layer 22.

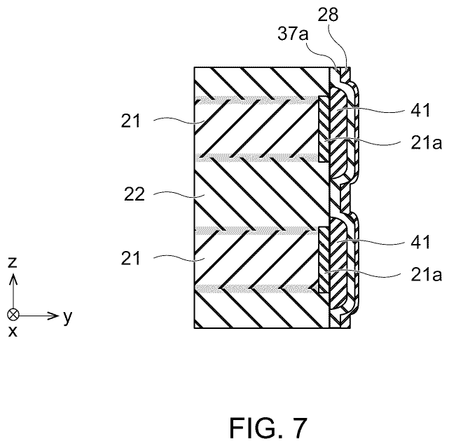

Next, as shown in FIG. 7, the charge storage film 28 is formed on the block film 37a. After the charge storage film 28 is formed, a part of the charge storage film 28 is removed. The part of the charge storage film 28 is removed by, for example, CDE (chemical dry etching).

Further, in the process shown in FIG. 7, the thickness in the y-direction of the charge storage film 28 in a region corresponding to the insulating film 41 is smaller than the thickness in the y-direction of the charge storage film 28 formed at a position of the opening of the insulating film 41. In other words, the charge storage film 28 is continuous in a direction (z-direction) in which the semiconductor layer 32 extends, thinning in the y-direction due to the insulating film 41. Therefore, a pseudo-separation structure of the charge storage film 28 is formed.

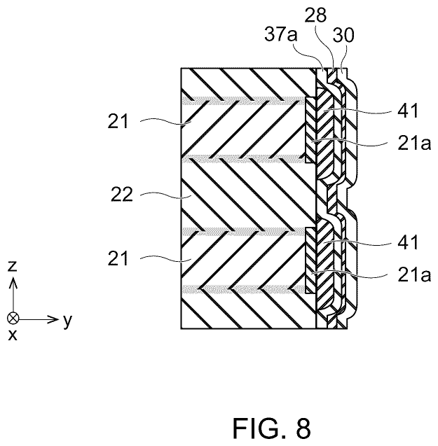

Next, as shown in FIG. 8, the tunnel insulating film 30 is formed on the charge storage film 28.

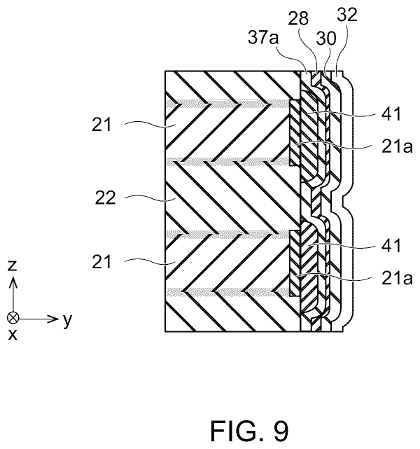

Next, as shown in FIG. 9, the semiconductor layer 32 is formed on the tunnel insulating film 30, and the core insulating film 33 (not shown) is formed on the semiconductor layer 32.

Thereafter, a groove that extends through the stacked body 20 is opened around the memory hole 24, and the sacrificial layer 22 is removed through the groove. By removing the sacrificial layer 22, the block film 37a is exposed. For the removal of the sacrificial layer 22, typically, heated phosphoric acid liquid chemical is used. Due to the liquid chemical treatment, a void is created in the site where the silicon nitride layer was removed. A void tracing the shape of the original sacrificial layer 22 is created. Note that the aforementioned transition layer may be removed.

Next, the block film 37 including, for example, an aluminum oxide is formed so as to cover a bottom surface and a side surface of the void. Note that for example, a barrier metal including TiN may be formed so as to cover the block film 37.

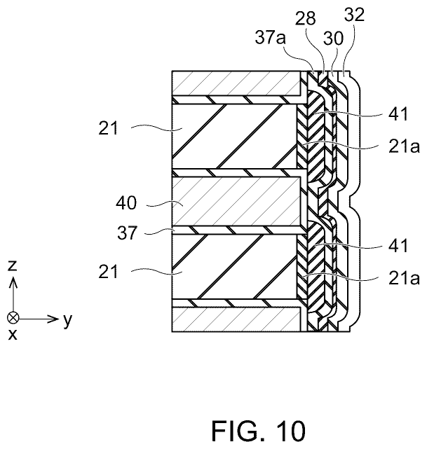

Next, the void is filled with a wiring material, for example, W (tungsten) to form the word line (electrode) 40. In this manner, the semiconductor memory device as shown in FIG. 1 and FIG. 10 is completed.

As described above, in the first embodiment, the insulating portion 21a is provided, as the base for the insulating film 41, in the end portion on the insulating film 41 side of the insulating layer 21. In this manner, the insulating film 41 can be formed in a more appropriate shape. As a result, the film shape of the insulating film 41 can be improved.

The density of the insulating portion 21a is different from the density of the insulating layer 21. The density of the insulating portion 21a is higher than the density of the insulating layer 21. This is because for example, by performing oxidation treatment, impurities are released so that the density of the insulating portion 21a increases. The density relation among the insulating portion 21a, the insulating layer 21, and the insulating film 41 is represented as insulating portion 21a>insulating layer 21>insulating film 41. For example, the density of the insulating portion 21a may be greater than 2.30 (g/cc) and the density of the insulating film 41 may be smaller than 2.05 (g/cc). Further, the density of the block film 37a is greater than the density of the insulating film 41 and smaller than the density of the insulating portion 21a. The density can be calculated from, for example, the reflectivity of an object to be measured using XRR (X-Ray Reflectivity).

Further, the charge storage film 28 is continuous along a direction (z-direction) in which the semiconductor layer 32 serving as a channel extends. However, the thickness in the y-direction of the charge storage film 28 is reduced due to the insulating film 41 and the charge storage film 28 that is thick in the y-direction is separated in the z-direction so that the charge release in the z-direction can be suppressed. In this manner, according to the present embodiment, deterioration of the charge retaining property can be suppressed.

Furthermore, the pseudo-separation structure of the charge storage film 28 has been described. However, the charge storage film 28 in the region corresponding to the insulating film 41 may not be provided. In other words, the charge storage film 28 may have a structure completely separated in the z-direction. For example, by increasing the removing amount of the charge storage film 28 in the process shown in FIG. 7, the charge storage film 28 is separated in the z-direction.

### Comparative Example

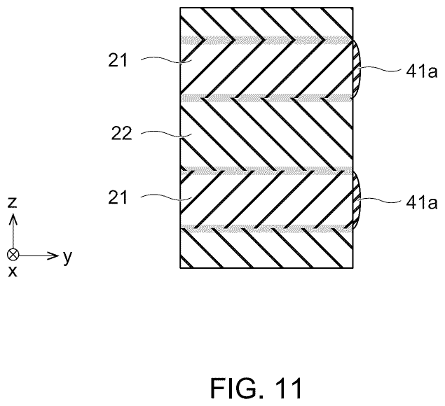

FIG. 11 to FIG. 13 are cross-sectional views showing an example of a semiconductor memory device manufacturing method of a comparative example. The comparative example differs from the first embodiment in that the insulating portion 21a is not formed. The process shown in FIG. 11 is performed after the same processes as those of FIG. 2 and FIG. 3.

After the memory hole 24 (see FIG. 3) is formed, as shown in FIG. 11, an insulating film 41a is selectively formed on the insulating layer 21 on the inner side surface of the memory hole 24. More specifically, the insulating film 41a is selectively grown from the insulating layer 21 (with the surface of the insulating layer 21 as a starting point).

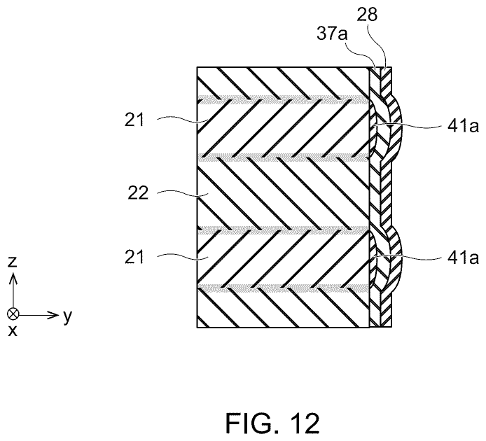

Next, as shown in FIG. 12, the block film 37a is formed on the sacrificial layer 22 and the insulating film 41a, and the charge storage film 28 is formed on the block film 37a.

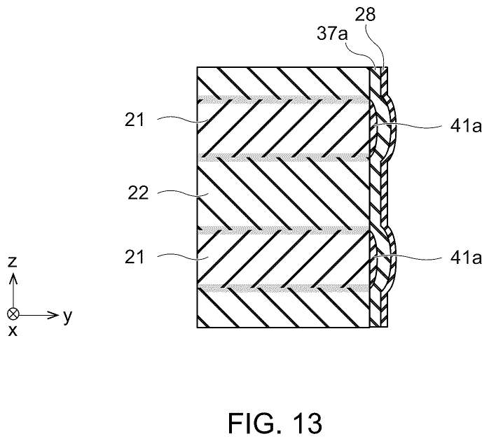

Next, as shown in FIG. 13, a part of the charge storage film 28 is removed. The part of the charge storage film 28 is removed by, for example, CDE.

Here, the cross-sectional shape of the insulating film 41a shown in FIG. 11 is in a lens-shape having a curved surface protruding toward the inside of the memory hole 24. This is because the transition layer includes a composition other than SiO₂, thereby making it difficult for the insulating film 41a on the transition layer to grow. As a result, it is difficult to appropriately form a step of the insulating film 41a. As shown in FIG. 13, it is difficult to appropriately form the pseudo-separation structure of the charge storage film 28.

By contrast, in the first embodiment, the insulating portion 21a including a substantially single composition of SiO₂ is formed on the end face of the insulating layer 21 so that the transition layer exposed from the inner side surface of the memory hole 24 can be eliminated. In this manner, as shown in FIG. 5, the cross-sectional shape of the insulating film 41 can be made closer to a rectangular shape. In other words, the film shape of the insulating film 41 can be improved. As a result, the pseudo-separation structure of the charge storage film 28 can be more appropriately formed.

### Second Embodiment

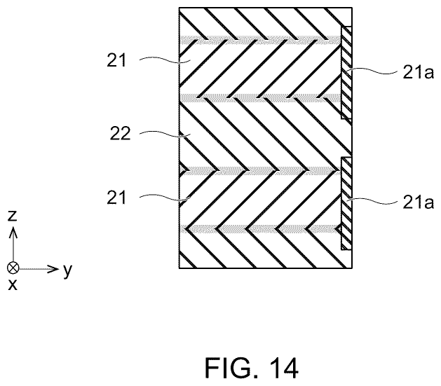

FIG. 14 to FIG. 16 are cross-sectional views showing an example of a semiconductor memory device manufacturing method according to a second embodiment. The second embodiment differs from the first embodiment in that the degree (amount) of oxidation of the sacrificial layer 22 is significant and the word line 40 is dented by the insulating portion 21a to form a step. The process shown in FIG. 14 is performed after the same processes as those of FIG. 2 and FIG. 3.

After the memory hole 24 is formed (see FIG. 3), as shown in FIG. 14, the insulating portion 21a is formed in the end portion, which is exposed from the inner side surface of the memory hole 24, of the insulating layer 21. More specifically, the oxygen concentration of the portion including the end face, which is exposed from the inner side surface of the memory hole 24, of the insulating layer 21 is made higher than the oxygen concentration of the portion including the boundary between the sacrificial layer 22 and the insulating layer 21.

The insulating portion 21a is formed by, for example, dry oxidation or radical oxidation, as in the same manner as the process shown in FIG. 4. Further, in the process shown in FIG. 14, the degree of oxidation of the sacrificial layer 22 is greater as compared to that in the process shown in FIG. 4. The insulating portion 21a shown in FIG. 14 protrudes longer in the z-direction as compared to the insulating portion 21a shown in FIG. 4 and reaches the inside of the sacrificial layer 22.

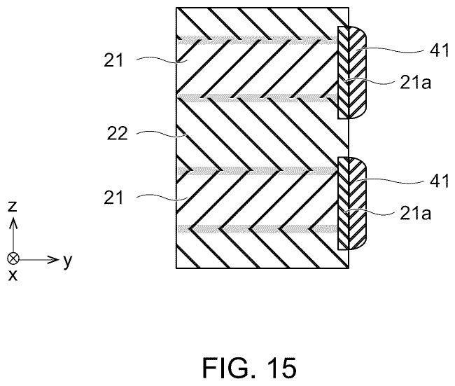

Next, as shown in FIG. 15, the insulating film 41 is selectively formed on the insulating portion 21a on the inner side surface of the memory hole 24. Note that the process shown in FIG. 15 is the same as the process shown in FIG. 5.

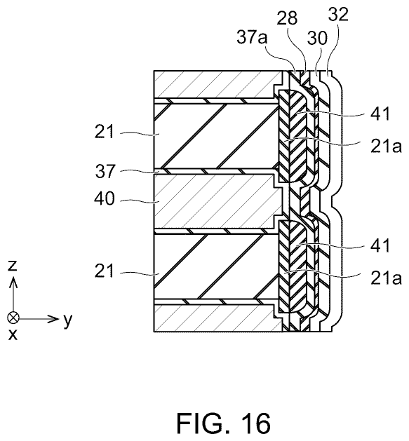

Thereafter, the same processes as those shown in FIG. 6 to FIG. 10 are performed. In this manner, the semiconductor memory device shown in FIG. 16 is completed.

As shown in FIG. 16, the insulating portion 21a is provided so as to protrude in the z-direction beyond an interface between the word line 40 and the insulating layer 21. The word line 40 includes a recess corresponding to the insulating portion 21a protruding beyond the interface between the word line 40 and the insulating layer 21. Thus, the step is formed in the cross section of the word line 40.

In the second embodiment, as with the first embodiment, the density of the insulating portion 21a is different from the density of the insulating layer 21. The density of the insulating portion 21a is higher than the density of the insulating layer 21. This is because for example, by performing oxidation treatment, impurities are released so that the density of the insulating portion 21a increases. The density relation among the insulating portion 21a, the insulating layer 21, and the insulating film 41 is represented as insulating portion 21a>insulating layer 21>insulating film 41. For example, the density of the insulating portion 21a may be greater than 2.30 (g/cc) and the density of the insulating film 41 may be smaller than 2.05 (g/cc).

As in the second embodiment, the degree of oxidation of the sacrificial layer 22 may be significant and the word line 40 may be dented by the insulating portion 21a to form a step. The semiconductor memory device according to the second embodiment can obtain the same effects as those of the first embodiment.

### Third Embodiment

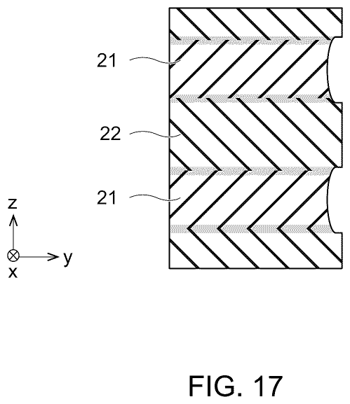

FIG. 17 to FIG. 20 are cross-sectional views showing an example of a semiconductor memory device manufacturing method according to a third embodiment. As compared to the first embodiment, in the third embodiment, the method for forming the insulating portion 21a is different. The process shown in FIG. 17 is performed after the same processes as those of FIG. 2 and FIG. 3.

After the memory hole 24 is formed (see FIG. 3), as shown in FIG. 17, the end portion, which is exposed from the inner side surface of the memory hole 24, of the insulating layer 21 is removed. The transition layer exposed from the inner side surface of the memory hole 24 is removed together with the insulating layer 21. The end portion of the insulating layer 21 is removed by, for example, HF wet treatment. Note that the end portion of the insulating layer 21 may be removed by CDE as long as the selectivity between the insulating layer 21 and the sacrificial layer 22 can be obtained. The cross-sectional shape of the region where the end portion of the insulating layer 21 is removed is in a lens-like shape having a curved surface. This is because the etching rate of the transition layer is lower than the etching rate of the center portion of the insulating layer 21.

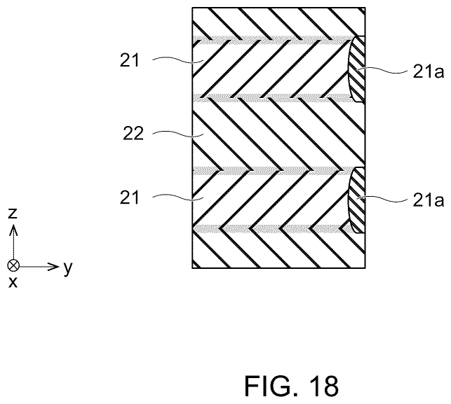

Next, as shown in FIG. 18, the insulating portion 21a is selectively formed in the region (void) where the end portion of the insulating layer 21 was removed. More specifically, by performing selective deposition, the insulating portion 21a is selectively grown from the remaining insulating layer 21 (with the surface of the insulating layer 21 as a starting point). The end face on the Z-Y cross section on the memory hole 24 side of the insulating portion 21a is nearly flat. This is because the growth of the insulating portion 21a in the vicinity of the transition layer is slower than the growth of the insulating portion 21a in the center portion of the insulating layer 21.

In the third embodiment, the density of the insulating portion 21a may be around the same as or different from the density of the insulating layer 21. For example, the density of the insulating portion 21a may be lower than the density of the insulating layer 21. Further, the density of the insulating portion 21a may be around the same as or different from the density of the insulating film 41. For example, the density of the insulating portion 21a may be higher than the density of the insulating film 41.

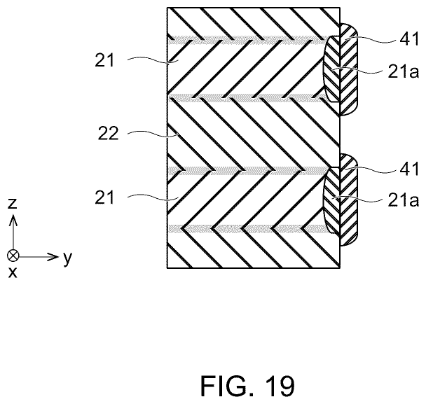

Next, as shown in FIG. 19, the insulating film 41 is selectively formed on the insulating portion 21a on the inner side surface of the memory hole 24. Note that the process shown in FIG. 15 is the same as the process shown in FIG. 5.

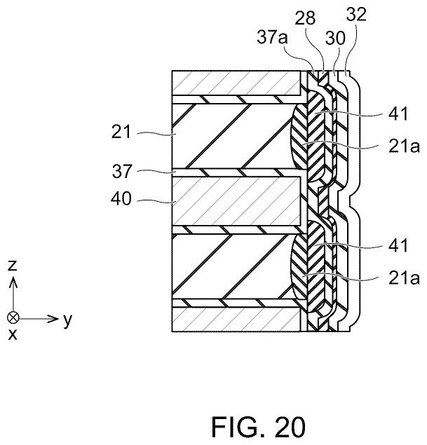

Thereafter, the same processes as those shown in FIG. 6 to FIG. 10 are performed. In this manner, the semiconductor memory device shown in FIG. 20 is completed.

The method for forming the insulating portion 21a may be changed as in the third embodiment. The semiconductor memory device according to the third embodiment can obtain the same effects as those of the first embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor memory device comprising:
a stacked body in which an electrode layer and an insulating layer are alternately stacked in a first direction;
a semiconductor layer disposed in the stacked body along the first direction;
a first insulating film disposed between the stacked body and the semiconductor layer along the first direction;
a charge storage film disposed between the stacked body and the first insulating film along the first direction;
a second insulating film disposed between the stacked body and the charge storage film along the first direction;
a third insulating film disposed between the insulating layer and the second insulating film; and
an insulating portion disposed in an end portion on a side of the third insulating film of the insulating layer, the insulating portion overlapping the electrode layer as viewed in the first direction, wherein
a density of the insulating portion differs from a density of the insulating layer.

2. The semiconductor memory device according to claim 1, wherein
the electrode layer comprises a fourth insulating film that includes a first portion disposed along the first direction and a second portion disposed along a second direction crossing the first direction, and a conductor surrounded by the fourth insulating film, and
the first portion and the insulating portion overlap with each other as viewed in the first direction.

3. The semiconductor memory device according to claim 1, wherein the density of the insulating portion is higher than the density of the insulating layer.

4. The semiconductor memory device according to claim 1, wherein the density of the insulating portion is higher than a density of the third insulating film.

5. The semiconductor memory device according to claim 1, wherein the insulating portion protrudes in the first direction beyond an interface between the electrode layer and the insulating layer.

6. The semiconductor memory device according to claim 5, wherein the electrode layer comprises a recess corresponding to the insulating portion.

7. The semiconductor memory device according to claim 1, wherein the charge storage film comprises, in a second direction crossing the first direction, a portion opposing the insulating layer and a portion opposing the electrode layer, a thickness of the portion opposing the electrode layer being greater than a thickness of the portion opposing the insulating layer.

8. The semiconductor memory device according to claim 2, wherein the fourth insulating film contains a metal oxide.

9. The semiconductor memory device according to claim 2, wherein in the second direction, the first portion and the second insulating film directly contact with each other.

10. A semiconductor memory device manufacturing method, comprising:
forming a stacked body in which a first layer and an insulating layer are alternately stacked in a first direction;
forming a hole extending in the stacked body in the first direction;
causing an oxygen concentration of a portion including an end face of the insulating layer exposed from the hole higher than an oxygen concentration of a portion including a boundary between the first layer and the insulating layer;
selectively forming a first film on the insulating layer, after causing the oxygen concentration of the portion including the end face higher than the oxygen concentration of the portion including the boundary;
forming a second film as an insulating body on the first layer and the first film;
forming a charge storage film on the second film;
forming a third film as an insulating body on the charge storage film; and
forming a semiconductor layer on the third film.

11. The semiconductor memory device manufacturing method according to claim 10, wherein
causing the oxygen concentration of the portion including the end face of the insulating layer exposed from the hole higher than the oxygen concentration of the portion including the boundary between the first layer and the insulating layer comprises performing oxidation treatment on an inner side surface of the hole.

12. The semiconductor memory device manufacturing method according to claim 11, wherein performing the oxidation treatment comprises oxidizing a transition layer between the first layer and the insulating layer, the transition layer being exposed from the hole.

13. The semiconductor memory device manufacturing method according to claim 11, wherein the oxidation treatment is dry oxidation or radical oxidation.

14. The semiconductor memory device manufacturing method according to claim 10, wherein
causing the oxygen concentration of the portion including the end face of the insulating layer exposed from the hole higher than the oxygen concentration of the portion including the boundary between the first layer and the insulating layer comprises:
removing an end portion of the insulating layer exposed from the hole; and
selectively forming an insulating portion on the insulating layer that is remaining.

15. The semiconductor memory device manufacturing method according to claim 11, wherein removing the end portion of the insulating layer comprises removing a transition layer between the first layer and the insulating layer, the transition layer being exposed from the hole.

16. The semiconductor memory device manufacturing method according to claim 14, wherein a density of the insulating portion is higher than a density of the insulating layer.

17. The semiconductor memory device manufacturing method according to claim 10, wherein
the first layer is a sacrificial layer,
the sacrificial layer is removed after the semiconductor layer is formed, and
an electrode layer is formed in a portion where the sacrificial layer is removed.

18. The semiconductor memory device manufacturing method according to claim 10, further comprising removing a part of the charge storage film before forming the third film.

19. The semiconductor memory device manufacturing method according to claim 10, wherein the second film is formed so as to directly contact the first layer.
